(19) United States
(12) Patent Application Publication
(10) Pub. No.: US 2025/0385694 A1
(43) Pub. Date: Dec. 18, 2025

(54) SYSTEM AND METHOD FOR POLAR ENCODING

(71) Applicant: JIO PLATFORMS LIMITED, Ahmedabad, Gujarat (IN)

(72) Inventors: Vinod Kumar SINGH, Navi Mumbai, Maharashtra (IN); Dileep Reddy VANAVASAM, Hyderabad, Telangana (IN); Smriti SINHA, Chandausi, Uttar Pradesh (IN); Aayush BHATNAGAR, Navi Mumbai, Maharashtra (IN); Pradeep Kumar BHATNAGAR, Navi Mumbai, Maharashtra (IN)

(73) Assignee: JIO PLATFORMS LIMITED, Ahmedabad, Gujarat (IN)

(21) Appl. No.: 18/880,061

(22) PCT Filed: Sep. 1, 2023
(86) PCT No.: PCT/IB2023/058654

§ 371 Date: Dec. 30, 2024

(30) Foreign Application Priority Data
Sep. 1, 2022 (IN) 202221049897

(51) Int. Cl. H03M 13/27; H03M 13/09; H03M 13/29

(52) U.S. Cl. CPC H03M 13/2707; H03M 13/09; H03M 13/2906

(57) ABSTRACT

The present disclosure provides a system and method for polar encoding in a communication system. A polar encoder includes a cyclic redundancy check (CRC) attachment module, an interleaver, a frozen bit mapper, and a polar transformer. The frozen bit mapper receives a master block comprising payload data and control information from the interleaver and fetches a pre-stored reliability sequence based on the control information in the master block to generate an encoded word.

### RESERVATION OF RIGHTS

A portion of the disclosure of this patent document contains material, which is subject to intellectual property rights such as, but are not limited to, copyright, design, trademark, Integrated Circuit (IC) layout design, and/or trade dress protection, belonging to Jio Platforms Limited (JPL) or its affiliates (hereinafter referred as owner). The owner has no objection to the facsimile reproduction by anyone of the patent document or the patent disclosure, as it appears in the Patent and Trademark Office patent files or records, but otherwise reserves all rights whatsoever. All rights to such intellectual property are fully reserved by the owner.

### FIELD OF DISCLOSURE

The embodiments of the present disclosure generally relate to encoder implementation for communication networks. More particularly, the present disclosure relates to a field programmable gate array (FPGA) implementation of a polar encoder for physical downlink control channel (PDCCH) format 2 fifth generation (5G) new radio (NR) physical layer.

### BACKGROUND OF DISCLOSURE

The following description of related art is intended to provide background information pertaining to the field of the disclosure. This section may include certain aspects of the art that may be related to various features of the present disclosure. However, it should be appreciated that this section be used only to enhance the understanding of the reader with respect to the present disclosure, and not as admissions of prior art.

Polar codes have been adopted as the coding scheme in the control channel of the 3rd Generation Partnership Project (3GPP) New Radio (NR) standard for 5G. Typically, when a polar encoder is implemented on a Radio Frequency System-on-Chip (RFSoC), various limitations like high utilization of resources and a requirement for supporting combinations data at run time are observed.

There is, therefore, a need in the art to provide a system and a method that can overcome the shortcomings of the existing prior arts.

### OBJECTS OF THE PRESENT DISCLOSURE

Some of the objects of the present disclosure, which at least one embodiment herein satisfies are as listed herein below.

An object of the present disclosure to provide an efficient encoder system.

An object of the present disclosure is to provide a Field Programmable Gate Arrays (FPGA) implementation of a polar encoder for physical downlink control channel (PDCCH) format 2 5G New Radio (NR) Physical layer.

An object of the present disclosure is to provide pre-stored required supported combinations data.

An object of the present disclosure is to provide a system and method that result in reduced usage of system resources.

### SUMMARY

This section is provided to introduce certain objects and aspects of the present disclosure in a simplified form that are further described below in the detailed description.

This summary is not intended to identify the key features or the scope of the claimed subject matter.

In an aspect, the present disclosure relates to a polar encoder, including a cyclic redundancy check (CRC) attachment module, an interleaver, a frozen bit mapper, and a polar transformer, wherein the frozen bit mapper is configured to receive a master block comprising payload data and control information from the interleaver, and fetch a pre-stored reliability sequence based on the control information in the master block to generate an encoded word.

In an embodiment, the CRC attachment module may be configured to obtain the payload data from a controller, add one or more CRC bits to the obtained payload data to generate the master block, and output the generated master block to the interleaver.

In an embodiment, the interleaver may be configured to interleave the payload data in the master block, and output the interleaved master block to the frozen bit mapper.

In an embodiment, the frozen bit mapper may be configured to map the payload data with one or more pre-stored reliability sequences based on the control information in the master block, obtain the encoded word based on the mapping, and output the obtained encoded word to the polar transformer.

In another aspect, the present disclosure relates to a method for encoding, including obtaining, by a cyclic redundancy check (CRC) attachment module, payload data from a controller to generate a master block, wherein the master block includes the payload data and control information, interleaving, by an interleaver, the payload data in the master block, receiving, by a frozen bit mapper, the master block from the interleaver, and fetching, by the frozen bit mapper, a pre-stored reliability sequence based on the control information in the master block to generate an encoded word.

In an embodiment, the method may include mapping, by the frozen bit mapper, the payload data with one or more pre-stored reliability sequences based on the control information in the master block, obtaining, by the frozen bit mapper, the encoded word based on the mapping, and outputting, by the frozen bit mapper, the obtained encoded word to a polar transformer.

In another aspect, a non-transitory computer readable medium that includes one or more instructions stored thereupon that when executed by a processor causes the processor to perform operations including obtaining payload data from a controller to generate a master block, wherein the master block includes the payload data and control information, interleaving the payload data in the master block, and fetching a pre-stored reliability sequence based on the control information in the master block to generate an encoded word.

In an embodiment, non-transitory computer readable medium may include one or more instructions stored thereupon that when executed by the processor causes the processor to perform operations including mapping the payload data with one or more pre-stored reliability sequences based on the control information in the master block, obtaining the encoded word based on the mapping, and outputting the obtained encoded word to a polar transformer.

### BRIEF DESCRIPTION OF DRAWINGS

The accompanying drawings, which are incorporated herein, and constitute a part of this disclosure, illustrate exemplary embodiments of the disclosed methods and systems in which like reference numerals refer to the same parts throughout the different drawings. Components in the drawings are not necessarily to scale, emphasis instead being placed upon clearly illustrating the principles of the present disclosure. Some drawings may indicate the components using block diagrams and may not represent the internal circuitry of each component. It will be appreciated by those skilled in the art that disclosure of such drawings includes the disclosure of electrical components, electronic components or circuitry commonly used to implement such components.

FIG. 1 illustrates an exemplary network architecture (100) in which or with which a proposed polar encoder may be implemented, in accordance with embodiments of the present disclosure.

FIG. 2 illustrates an exemplary high-level block diagram (200) of a polar encoder, in accordance with an embodiment of the present disclosure.

FIG. 3 illustrates a bit field (300) associated with a cyclic redundancy check (CRC) attachment control information, in accordance with an embodiment of the present disclosure.

FIG. 4 illustrates a pin diagram (400) representation of the polar encoder, in accordance with an embodiment of the present disclosure.

FIG. 5 illustrates an exemplary computer system (500) in which or with which embodiments of the present disclosure may be implemented.

The foregoing shall be more apparent from the following more detailed description of the disclosure.

### DETAILED DESCRIPTION OF DISCLOSURE

In the following description, for the purposes of explanation, various specific details are set forth in order to provide a thorough understanding of embodiments of the present disclosure. It will be apparent, however, that embodiments of the present disclosure may be practiced without these specific details. Several features described hereafter can each be used independently of one another or with any combination of other features. An individual feature may not address all of the problems discussed above or might address only some of the problems discussed above. Some of the problems discussed above might not be fully addressed by any of the features described herein.

The ensuing description provides exemplary embodiments only, and is not intended to limit the scope, applicability, or configuration of the disclosure. Rather, the ensuing description of the exemplary embodiments will provide those skilled in the art with an enabling description for implementing an exemplary embodiment. It should be understood that various changes may be made in the function and arrangement of elements without departing from the spirit and scope of the disclosure as set forth.

Specific details are given in the following description to provide a thorough understanding of the embodiments. However, it will be understood by one of ordinary skill in the art that the embodiments may be practiced without these specific details. For example, circuits, systems, networks, processes, and other components may be shown as components in block diagram form in order not to obscure the embodiments in unnecessary detail. In other instances, well-known circuits, processes, algorithms, structures, and techniques may be shown without unnecessary detail in order to avoid obscuring the embodiments.

Also, it is noted that individual embodiments may be described as a process which is depicted as a flowchart, a flow diagram, a data flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed but could have additional steps not included in a figure. A process may correspond to a method, a function, a procedure, a subroutine, a subprogram, etc. When a process corresponds to a function, its termination can correspond to a return of the function to the calling function or the main function.

The word “exemplary” and/or “demonstrative” is used herein to mean serving as an example, instance, or illustration. For the avoidance of doubt, the subject matter disclosed herein is not limited by such examples. In addition, any aspect or design described herein as “exemplary” and/or “demonstrative” is not necessarily to be construed as preferred or advantageous over other aspects or designs, nor is it meant to preclude equivalent exemplary structures and techniques known to those of ordinary skill in the art. Furthermore, to the extent that the terms “includes,” “has,” “contains,” and other similar words are used in either the detailed description or the claims, such terms are intended to be inclusive-in a manner similar to the term “comprising” as an open transition word-without precluding any additional or other elements.

Reference throughout this specification to “one embodiment” or “an embodiment” or “an instance” or “one instance” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

The present disclosure provides a polar encoder with resource optimization. In some embodiments, the encoder includes pre-stored combinations data required to support customized use cases in outdoor small cell (ODSc) units. In some embodiments, the pre-stored combinations do not require any bit array (BA) table to be generated and pushed from a programmable system (PS) to a programmable logic (PL) in a field programmable gate array (FPGA) based Radio Frequency System-on-Chip (RFSoC).

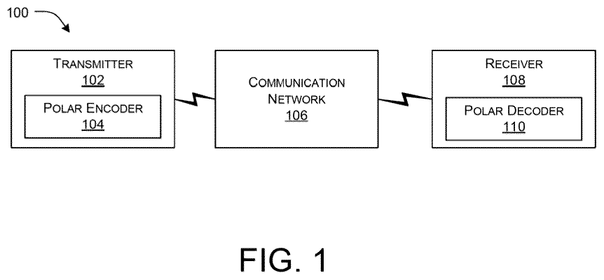

The various embodiments throughout the disclosure will be explained in more detail with reference to FIGS. 1-5.

FIG. 1 illustrates an exemplary network architecture (100) in which or with which a proposed polar encoder may be implemented, in accordance with embodiments of the present disclosure.

Referring to FIG. 1, the network architecture (100) includes a transmitter (102) including a polar encoder (104). In some embodiments, the transmitter (102) transmits an encoded information through a communication network (106) to a receiver (108). The receiver (108) may include a polar decoder (110) for decoding the encoded information received from the transmitter (102). In some embodiments, the communication network (106) may include a fifth generation (5G) communication network. Further, the transmitter (102) and the receiver (108) may include the polar encoder (104) and the polar decoder (110), respectively, operating in a physical downlink control channel (PDCCH) format 2.

In some embodiments, the polar encoder (104) may include pre-stored combination data required to support customized use cases in outdoor small cell (ODSc) units.

In some embodiments, an access point or a base station may include the polar encoder (104) and a user equipment (UE) may include an associated decoder (110). In some other embodiments, the (UE) may include the polar encoder (104) and the base station may include the associated decoder (110).

Although FIG. 1 shows exemplary components of the network architecture (100), in other embodiments, the network architecture (100) may include fewer components, different components, differently arranged components, or additional functional components than depicted in FIG. 1. Additionally, or alternatively, one or more components of the network architecture (100) may perform functions described as being performed by one or more other components of the network architecture (100).

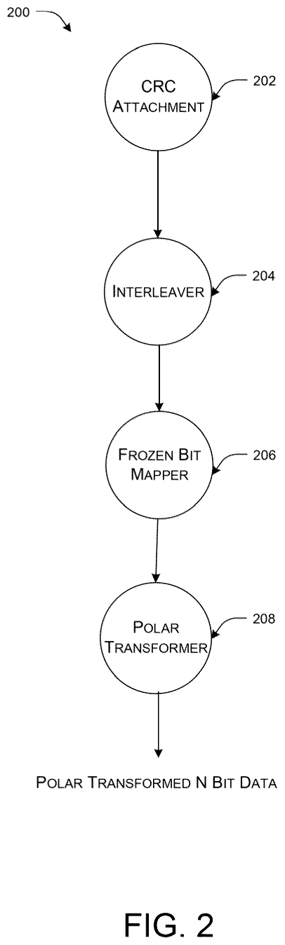

FIG. 2 illustrates a high-level block diagram (200) of a polar encoder, in accordance with an embodiment of the present disclosure.

Referring to FIG. 2, the block diagram (200) includes a cyclic redundancy check (CRC) attachment module (202), an interleaver (204), a frozen bit mapper (206), a polar transformer (208). Referring to FIG. 2, the CRC attachment module (202) receives a ‘k’ bit payload from a controller (not shown). For example, the CRC attachment module (202) may be interfaced with a PS-to-PL controller to obtain one or more control words and the ‘k’ bit payload. The CRC attachment module (202) may attach a 24-bit CRC to the ‘k’ bit payload to obtain an output A=(k+24) bit. Further, the CRC attachment module (202) requires one or more control information for its operation. For example, without limitation, the one or more control information includes at least one of a Radio Network Temporary

Identifier (RNTI), number of payload bits ‘k’, length of encoded word ‘N’, and a CRC INIT flag. The CRC attachment module (202) may then forward the CRC attached ‘A’ bit payload and the ‘N’ and ‘k’ information to the interleaver (204).

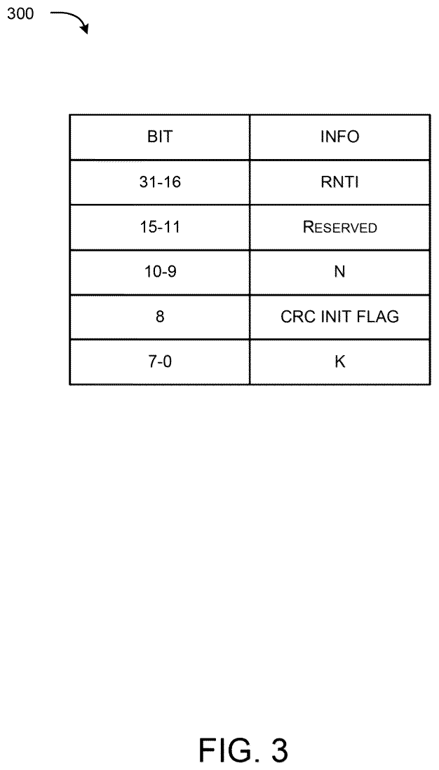

In some embodiments, the control information includes 32 bits, and the bit format or bit field of the control information is shown in FIG. 3.

Referring to FIG. 3, the length of the encoded word ‘N’ is specified by 2 bits. For example, without limitation, if the bits 9-10 are 01, then N is 128 bits long, if the bits 9-10 are 10, then N is 256 bits long, and if the bits 9-10 are 11, then N is 256 bits long.

Referring to FIG. 2, after attaching the CRC bits to the ‘k’ bit payload, the CRC attachment module (202) transmits the output ‘A’ along with the control information to the interleaver (204). The output ‘A’ along with the control information may be referred as a master block. In an example embodiment, the output of the CRC attachment module (202) is 176 bit long with 164 least significant bits (LSB) as data and the next 10 bits representing the values of ‘k’ and ‘N’, of which the 8 LSB bits represent ‘k’ and 2 most significant bits (MSB) represent ‘N’. The interleaver (204) may interleave the information bits received from the CRC attachment module (202) based on the control information and the k value. For example, the interleaver (204) may interleave the ‘A’ bit payload. Further, the interleaver (204) may pass the interleaved data to the frozen bit mapper (206).

In some embodiments, the frozen bit mapper (206) obtains the control data i.e., the size of ‘N’ and ‘k’ from the master block and fetches a reliability sequence for that combination from an internal memory. The frozen bit mapper (206) may further map the interleaved data to a ‘N’ bit long code word based on the reliability sequence. The frozen bit mapper (206) may the output the ‘N’ bit long code word to the polar transformer (208). In some embodiments, the reliability sequence associated with various ‘N’ and ‘k’ are stored in a memory available on the FPGA, thereby reducing the PS-PL interface at the frozen bit mapper (206).

Referring to FIG. 2, the polar transformer (208) may perform polar transformation on the ‘N’ bit code word by multiplying the N bit code word with a N*N Kronecker matric using the below transformation:

$$d = {uG}_{N}$$

where u represents ‘N’ bit input and G_{N} denotes n-th power of Kronecker Matrix of G₂, where G₂ is given as:

$${G}_{2} = [ \begin{matrix}1 & 0 \\ 1 & 1\end{matrix} ]$$

The information related to ‘N’ is provided by the frozen bit mapper (206). In some embodiments, the output port of the polar transformer (208) may be 128-bit long. The encoded codeword from the polar transformer may be forwarded to the next module, for example, a rate matching block.

In some embodiments, to optimize the resources used for calculating the polar transform for large number of bits like 512, the polar transformer (208) takes 32 bits at a time for encoding. By way of example, without limitations, if the polar transformer (208) receives a 128 bit block, the polar transformer (208) may encode each 32 bit block starting with a first set of 32 bits from the LSB bits of the 128 bit block. Each 32 bit block (in this example for 128 bits there may be four 32 bit blocks) from the 128 bits block is polar transformed individually and may be stored in a set of registers, for example, U4, U3, U2, and U1, respectively. The final encoded data dₒᵤₜ which is 128 bit long may be obtained using the below formula.

$${d}_{out} = \{ u 2 \hat{} u 1 \hat{} u 3 \hat{} u 4 , u 2 \hat{} u 4 , u 3 \hat{} u 4 , u 4 \}$$

Similarly, the above function may be used twice to encode 256 bits and 4 times to encode 512 bits. For 256 bits, the polar transform is applied to the two sets of 128 encoded bits, obtained as an output of the function mentioned above. The Table 1 below shows the resource utilization report based on using a pre-stored reliability sequence.

TABLE 1

| | | | Block | | |
|---|---|---|---|---|---|
| | Look | | Random | | Digital |
| | up | Flip | access | Unified | Signal |
| | Table | flops | memory | RAM | Processors |
| Module | (LUTs) | (FFs) | (BRAM) | (URAM) | (DSPs) |
| CRC | 337 | 650 | 0 | 0 | 0 |
| Interleaving block | 392 | 175 | 0 | 0 | 0 |
| Frozen bit | 1904 | 787 | 2 | 0 | 0 |
| Polar transform | 1602 | 1692 | 0 | 0 | 0 |
| Total resources for Polar | 4233 | 3304 | 2 | 0 | 0 |
| encoder | | | | | |
| Resources Utilization in % | 0.99 | 0.38 | 0.18 | 0 0 | 0.0 |
| Total Resources Available | 425280 | 850560 | 1080 | 80 | 4272 |
| (ZCU111 Ultrascale + | | | | | |
| RFSoC) | | | | | |

As may be observed from Table 1 above, the use of pre-stored reliability sequence reduces the usage of resources in the FPGA. For example, the resource utilization stands at less than 2% when implemented on Xilinx RFSoC ZCU111 evaluation board still it is able to support the various combinations mentioned below in Table 2. Since there is no bit allocation (BA) table that is required to be generated and pushed from PS to PL in the FPGA system, the polar encoder does not require any Advanced extensible Interface (AXI) full/AXI lite interface, thus saving on memory storage and LUTs/FFs.

In some embodiments, the polar encoder may support the following combinations:

TABLE 2

| Payload Size (A) | Codeword length (N) |
|---|---|
| 20 | 128, 256, 512 |
| 32 | 512 |
| 33-64 | 128, 256, 512 |

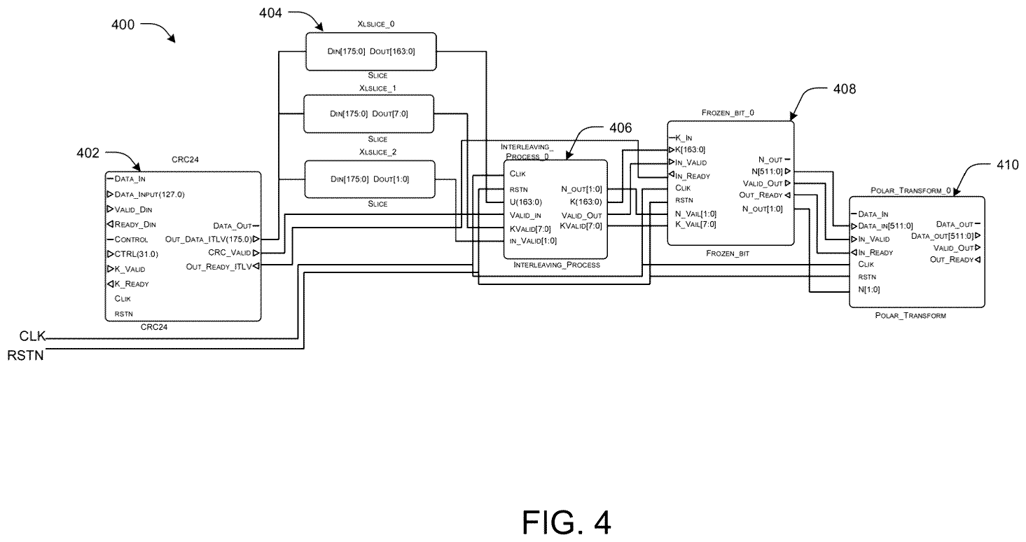

FIG. 4 illustrates a pin diagram (400) representation of the polar encoder, in accordance with an embodiment of the present disclosure.

Referring to FIG. 4, an interconnection between different integrated circuit modules for example, a CRC module (402), a slicing module (404), an interleaving module (406), frozen bit module (408), and a polar transformer module (410) for performing the encoding operation is shown.

In some embodiments, the polar encoder has three ports which may be interfaced with the external inputs, for example, input from a controller (not shown) or a rate matching circuit (not shown). The three main ports of the polar encoder may be given as Control, Data_in, and Data_Out and their respective operational details are given as follows:
1. Control port is an AXIS port with 32 bit data port width. The data structure of the port is mentioned in FIG. 3.
2. Data_in is the data port which accepts the payload from the controller. It is an AXIS port with data port width as 128. LSB payload is provided first and if payload>128, then the MSB payload is given in the next clock cycle.
3. Data_Out is the output interface. It is an AXIS port with data port width as 128.

A person of ordinary skill in the art will appreciate that these are mere examples, and in no way, limit the scope of the present disclosure.

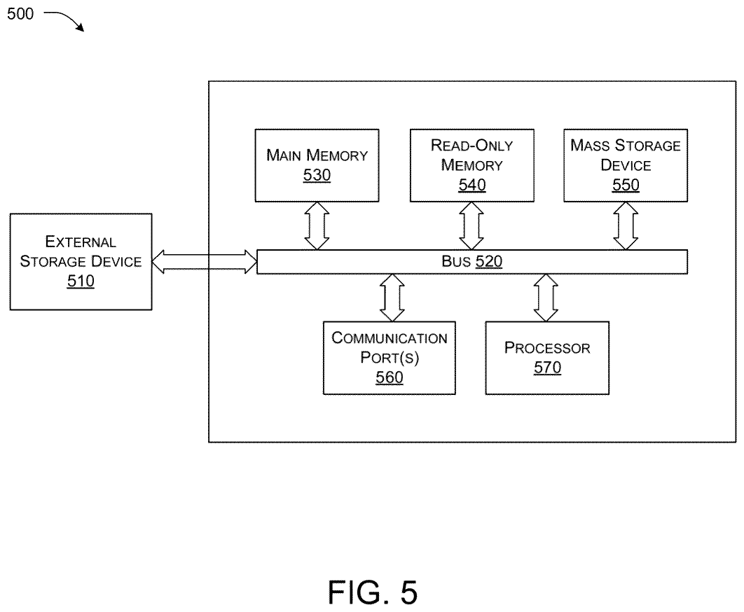

FIG. 5 illustrates an exemplary computer system (500) in which or with which embodiments of the present disclosure may be utilized.

As shown in FIG. 5, the computer system (500) may include an external storage device (510), a bus (520), a main memory (530), a read-only memory (540), a mass storage device (550), communication port(s) (560), and a processor (570). A person skilled in the art will appreciate that the computer system (500) may include more than one processor and communication ports. The processor (570) may include various modules associated with embodiments of the present disclosure. The communication port(s) (560) may be any of an RS-232 port for use with a modem-based dialup connection, a 10/100 Ethernet port, a Gigabit or 10 Gigabit port using copper or fibre, a serial port, a parallel port, or other existing or future ports. The communication port(s) (560) may be chosen depending on a network, such a Local Area Network (LAN), Wide Area Network (WAN), or any network to which the computer system (500) connects. The main memory (530) may be random access memory (RAM), or any other dynamic storage device commonly known in the art. The read-only memory (540) may be any static storage device(s) including, but not limited to, a Programmable Read Only Memory (PROM) chips for storing static information e.g., start-up or basic input/output system (BIOS) instructions for the processor (570). The mass storage device (550) may be any current or future mass storage solution, which may be used to store information and/or instructions.

The bus (520) communicatively couples the processor (570) with the other memory, storage, and communication blocks. The bus (520) may be, e.g. a Peripheral Component Interconnect (PCI)/PCI Extended (PCI-X) bus, Small Computer System Interface (SCSI), Universal Serial Bus (USB), or the like, for connecting expansion cards, drives, and other subsystems as well as other buses, such a front side bus (FSB), which connects the processor (570) to the computer system (500).

Optionally, operator and administrative interfaces, e.g. a display, keyboard, and a cursor control device, may also be coupled to the bus (520) to support direct operator interaction with the computer system (500). Other operator and administrative interfaces may be provided through network connections connected through the communication port(s) (560). In no way should the aforementioned exemplary computer system (500) limit the scope of the present disclosure.

While considerable emphasis has been placed herein on the preferred embodiments, it will be appreciated that many embodiments can be made and that many changes can be made in the preferred embodiments without departing from the principles of the disclosure. These and other changes in the preferred embodiments of the disclosure will be apparent to those skilled in the art from the disclosure herein, whereby it is to be distinctly understood that the foregoing descriptive matter to be implemented merely as illustrative of the disclosure and not as limitation.

### ADVANTAGES OF THE PRESENT DISCLOSURE

The present disclosure provides an efficient encoder system.

The present disclosure provides a Field Programmable Gate Array (FPGA) implementation of a polar encoder for physical downlink control channel (PDCCH) format 2 5G NR Physical layer.

The present disclosure facilitates reduced usage of system resources by implementing pre-stored required supported combinations data or reliability sequence.

We claim:

1. A polar encoder (104), comprising:
a cyclic redundancy check (CRC) attachment module (202);
an interleaver (204);
a frozen bit mapper (206); and
a polar transformer (208),
wherein the frozen bit mapper (206) is configured to:
receive a master block comprising payload data and control information from the interleaver (204); and
fetch a pre-stored reliability sequence based on the control information in the master block to generate an encoded word.

2. The polar encoder (104) as claimed in claim 1, wherein the CRC attachment module (202) is configured to:
obtain the payload data from a controller;
add one or more CRC bits to the obtained payload data to generate the master block; and
output the generated master block to the interleaver (204).

3. The polar encoder (104) as claimed in claim 2, wherein the interleaver (204) is configured to:
interleave the payload data in the master block; and
output the interleaved master block to the frozen bit mapper (206).

4. The polar encoder (104) as claimed in claim 1, wherein the frozen bit mapper (206) is configured to:
map the payload data with one or more pre-stored reliability sequences based on the control information in the master block;
obtain the encoded word based on the mapping; and
output the obtained encoded word to the polar transformer (208).

5. A method for encoding, comprising:
obtaining, by a cyclic redundancy check (CRC) attachment module (202), payload data from a controller to generate a master block, wherein the master block comprises the payload data and control information;
interleaving, by an interleaver (204), the payload data in the master block;
receiving, by a frozen bit mapper (206), the master block from the interleaver (204); and
fetching, by the frozen bit mapper (206), a pre-stored reliability sequence based on the control information in the master block to generate an encoded word.

6. The method as claimed in claim 5, comprising:
mapping, by the frozen bit mapper (206), the payload data with one or more pre-stored reliability sequences based on the control information in the master block;
obtaining, by the frozen bit mapper (206), the encoded word based on the mapping; and
outputting, by the frozen bit mapper (206), the obtained encoded word to a polar transformer (208).

7. A non-transitory computer readable medium that comprises one or more instructions stored thereupon that when executed by a processor causes the processor to perform operations comprising:
obtaining payload data from a controller to generate a master block, wherein the master block comprises the payload data and control information;
interleaving the payload data in the master block; and
fetching a pre-stored reliability sequence based on the control information in the master block to generate an encoded word.

8. The non-transitory computer readable medium as claimed in claim 7, comprising one or more instructions stored thereupon that when executed by the processor causes the processor to perform operations comprising:
mapping the payload data with one or more pre-stored reliability sequences based on the control information in the master block;
obtaining the encoded word based on the mapping; and
outputting the obtained encoded word to a polar transformer (208).
